(19) United States
(12) Patent Application Publication
(10) Pub. No.: US 2009/0302474 A1
(43) Pub. Date: Dec. 10, 2009

(54) Atomic laminates for diffucion barrier applications

(75) Inventors: Katayun Barmak, White Plains, NY (US); Hyungjun Kim, Lagrangeville, NY (US); Ismail C. Noyan, Chappaqua, NY (US); Stephen M. Rossnagel, Pleasantville, NY (US)

Correspondence Address: ROBBIN PENISTON, 54 OUTLOOK DR, HILLSBORO, MO, 63050, US

(73) Assignee: International Business Machines Corporation

(21) Appl. No.: 12/583,108

(22) Filed: Aug. 13, 2009

Related U.S. Application Data
(62) Division of application No. 10/674,853, filed on Sep. 29, 2003.

(51) Int. Cl. H01L 23/532

(52) U.S. Cl. 257/751; 257/E23.154

(57) ABSTRACT

The present invention relates to a very thin multilayer diffusion barrier for a semiconductor device and fabrication method thereof. The multilayer diffusion barrier according to the present invention is fabricated by forming a very thin, multilayer diffusion barrier composed of even thinner sub-layers, where the sub-layers are only a few atoms thick. The present invention provides a diffusion barrier layer for a semiconductor device which is in a substantially amorphous state and thermodynamically stable, even at high temperatures.

### TECHNICAL FIELD

These teachings relate generally to semiconductor technology and, more specifically, relate to the formation and application of diffusion barriers used in interconnect technology, and elsewhere, to separate materials which are in close proximity and which may undergo temperature cycling.

### BACKGROUND

A diffusion barrier is a thin layer of material, which could be a metal, a metal nitride, or an oxide, that separates two different materials that would interact chemically either at room temperature or at elevated temperatures. In the field of interconnect technology, one common application of a diffusion barrier is for the encapsulation of copper metal lines and vias which form elements of wiring structures. Because of the tendency of copper to react rapidly and detrimentally with silicon and insulators, use of a diffusion barrier is necessary. Without a diffusion barrier, copper would diffuse out from the metal lines, degrading the properties of the inter-layer dielectric (ILD), the silicon junction, and many of the other materials used in the fabrication of the circuit. The diffusion barrier additionally prevents contaminants from diffusing into the copper metal features. These contaminants include oxygen, water, other metals, solvents, etc., all of which have the potential to cause significant changes to the copper metal and decrease its electrical conductivity.

Conventional interconnect technology solutions have included a thin layer of tantalum nitride (TaN), which is used, often in conjunction with a thin layer of tantalum (Ta), as the diffusion barrier to limit diffusion both into and out from copper circuit features. The typical thicknesses of these layers are in the range of 70-150 angstroms (7-15 nm). The failure temperature of this material can, in some cases, be measured and it has been found that the minimum failure temperature for this barrier generally exceeds 700-730 degrees centigrade.

Diffusion barriers fail due to transport of atoms across the barrier. This transport occurs most easily along grain boundaries, which are present in all polycrystalline material. The activation energy for movement of impurity atoms along the grain boundary is typically comparable to surface diffusion, rather than bulk diffusion, and this is typically one half or less of the bulk diffusion activation energy. Since these are thermally activated processes, grain boundary diffusion occurs many times faster than bulk diffusion at any given temperature. Hence, it is generally considered that the primary failure mechanism for a diffusion barrier is by grain boundary diffusion.

Conventional diffusion barriers are generally divided into sacrificial barriers and stuffed barriers. Sacrificial barriers are thermodynamically unstable. Sacrificial barriers react with interconnection material or substrate material to prevent the diffusion of the material. The sacrificial barrier is consumed according to the reaction so that it loses its function as a diffusion barrier when it has been completely consumed. This finite lifetime is the major limitation of sacrificial barriers. Stuffed barriers prevent diffusion by filling other materials into grain boundaries that are paths for diffusion.

Attempts have been made to develop amorphous diffusion barriers. The addition of silicon (Si) to tantalum nitride (TaN) results in an amorphous material, which functions well as a diffusion barrier due to its thermal stability and absence of grain boundaries. Other approaches have used a multilayer stack of materials. These can be dissimilar materials, or they can be the same material which is deposited in thin layers, perhaps followed by air exposure to oxidize the surface. These stacks of films are composed of crystallized films, each having many grain boundaries. However, due to the discontinuous deposition process, the grain boundaries from each layer do not align with that of the next, and this slows diffusion considerably (reference in this regard may be had to Clarke, “Method of Depositing Materials on a Wafer to Eliminate the Effect of Cracks in the Deposition”, U.S. Pat. No. 6,086,947).

Neither of these solutions is totally acceptable from a manufacturing process point of view. A ternary compound, tantalum silicon nitride (TaSiN), is difficult to fabricate reliably with satisfactory chemical control. And the multilayer, discontinuous grain boundaries approach does not scale well to the very thin thicknesses required for barriers in future interconnect generations, where the total diffusion barrier thickness is preferably no more than a few nanometers.

### SUMMARY OF THE PREFERRED EMBODIMENTS

The foregoing and other problems are overcome, and other advantages are realized, in accordance with the currently preferred embodiments of these teachings.

Accordingly, a method is provided for the formation of very thin, multilayer diffusion barriers composed of even thinner sub-layers, where the sub-layers are only a few atoms thick. An aspect of this invention when forming these layers is to use the interfaces between each of the sub-layers to inhibit the formation of a crystalline lattice in each sub-layer. A strong bond between each of the sub-layers perturbs the regular crystalline structure of the sub-layer, as long as the sub-layer remains very thin. Since the surface energies dominate the bulk binding energies, the sub-layer remains disordered and in a substantially amorphous state (i.e., essentially free of a regular crystalline structure). The lack of formation of a lattice within each sub-layer results in no grain boundary formation, and hence, no pathways for inter diffusion of metals through the barrier as long as the multilayer remains amorphous.

### BRIEF DESCRIPTION OF THE DRAWINGS

The foregoing and other aspects of these teachings are made more evident in the following Detailed Description of the Preferred Embodiments, when read in conjunction with the attached Drawing Figures, wherein:

FIG. 1 illustrates a conventional interconnect feature showing a copper via and line as well as a diffusion barrier;

FIG. 2 shows a close up of a conventional diffusion barrier with grain boundaries and pathways for interdiffusion;

FIG. 3 shows a schematic of a multilayer diffusion barrier composed of atomic laminant films according to the present invention;

FIG. 4 is a close up of the atomic laminant structure according to the present invention; and

FIG. 5 illustrates a cross-sectional view of a portion of an integrated circuit showing a diffusion barrier in accordance with the present invention, a via, and a substrate material.

### DETAILED DESCRIPTION OF THE PREFERRED EMBODIMENTS

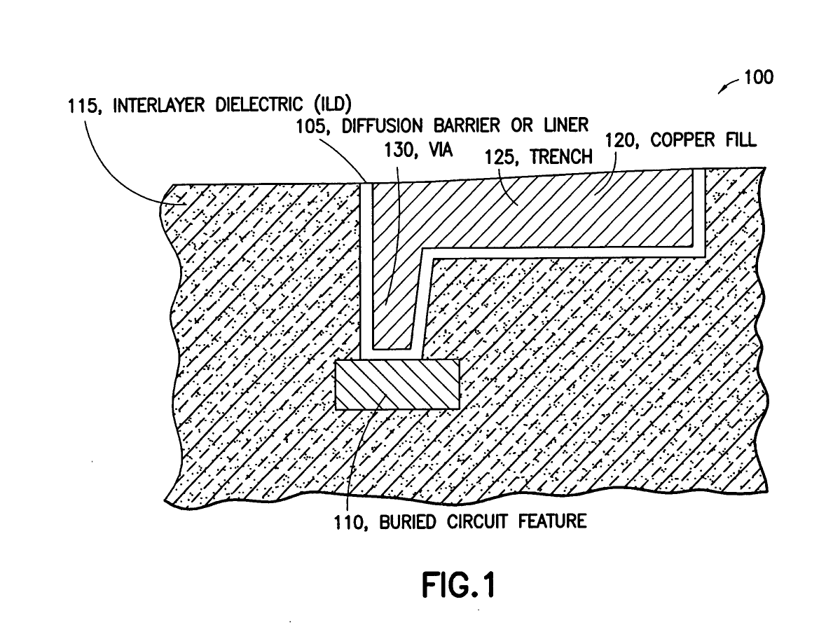

Referring to FIG. 1, a cross sectional view of a simple diffusion barrier schematic 100 is shown. In this case, a diffusion barrier 105 is present between a copper circuit feature 120 and the surrounding interlayer dielectric (ILD) 115. The barrier 105 in this case also separates the copper conductor 120 from the buried metallic circuit feature 110, which may be composed of another material other than copper, such as a silicide, tungsten (W), aluminum (Al), etc. A trench 125 and via 130 are also shown.

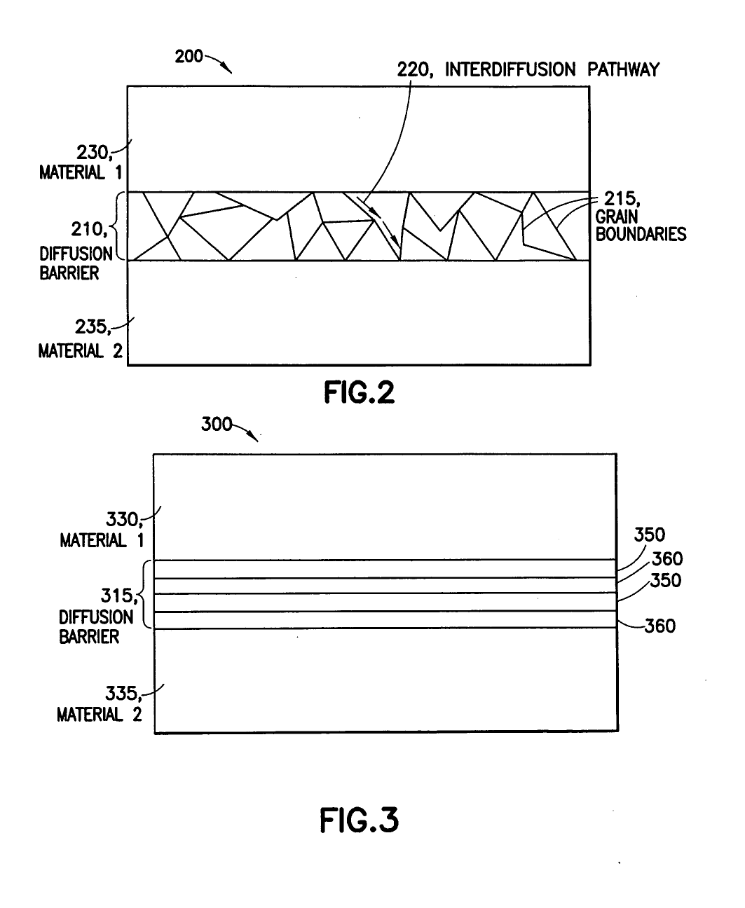

An enlarged view of this last interface is shown in FIG. 2, which shows the microstructure of the barrier material 210. In this figure, the grain boundaries 215 can be observed to be pathways 220 through the diffusion barrier 210 which allows one or both of the materials 230, 235 present to pass into the other, and thus, potentially degrade the electrical performance or reliability of the circuit.

Conventional diffusion barrier materials include crystalline materials such as titanium nitride (TiN), and tantalum nitride (TaN). Copper is able to diffuse through the grain boundaries 215 in these materials 230, 235, as the crystalline materials form the grain boundaries 215 where two adjacent crystalline structures meet. Copper atoms drift through the grain boundaries 215 and diffuse into the underlying structures 230, 235.

A diffusion barrier 315 in accordance with this invention is shown in FIG. 3. The diffusion barrier 315 includes a stack of very thin layers 350, 360, generally of alternating composition. In most embodiments, this might be a stack of two alternating layers of materials, such as copper (Cu) and tantalum (Ta). However, it is also possible to use three or more different materials.

Each layer preferably has a thickness in a range of about two atoms to about fifteen atoms (0.4 to 4.5 nm), and more preferably has a thickness in a range of about two atoms to about ten atoms (0.4 to 3.0 nm), and even more preferably has a thickness in a range of about two atoms to about five atoms (0.4 to 1.5 nm).

To overcome the problems associated with grain boundaries mentioned above, the diffusion barrier layers 350, 360 in the present invention are substantially amorphous. Since the diffusion barrier layers 350, 360 are not crystalline, there are no grain boundaries to extend through the layer 315 for the copper (or other chemical species) to drift or diffuse through.

For purposes of illustration, substrate 300 is shown as a simple planar structure. The method of the present invention may be applied to more complicated structures and is not limited to the illustrative example. For example, multilayer interconnects and vias could be formed using the present method as well as simple contact openings that provide electrical contact to a device.

Referring again to FIG. 3, after the substrate 300 is prepared, a diffusion barrier material composed of atomic laminant films 350, 360 is deposited. In order to avoid the formation of a crystalline structure the diffusion barrier sub-layers 350, 360 are preferably no more than 2-5 atomic layers thick (0.4 to 1.5 nm), and thus, the resulting structure has the form of an essentially or substantially amorphous material thereby beneficially inhibiting diffusion through the material. It is to be noted that there are no specific or special requirements for the preparation of the substrate prior to the multilayer deposition process.

The diffusion barrier sub-layer material 350, 360 is preferably deposited by physical vapor deposition (PVD) (sputtering and /or evaporation). Atomic layer deposition (ALD) can also be used to deposit the sub-layers 350, 360. Atomic layer deposition (also known as atomic layer epitaxy) is a process for depositing thin layers of solid materials from two or more vapor precursors. Advantages of atomic layer deposition include low impurities content, low processing temperatures, ultra thin film deposition and excellent thickness uniformity over large substrate areas. Chemical vapor deposition (CVD) could also be used to deposit the sub-layers 350, 360.

As illustrated by FIG. 3 the diffusion barrier sub-layer materials 350, 360 are alternately deposited a plurality of times. The deposition process could be repeated to provide between three and several hundred different sub-layers, as there is no functional maximum for the number of sub-layers. The effect of suppressing lattice formation is driven by the interfaces between each sub-layer and each interface for each successive sub-layer is independent of the next sub-layer. Preferably, between three and ten sub-layers are formed. The overall thickness of the conductive diffusion barrier 315 is preferably between 30 and 50 angstroms. Also, it is within the scope of the present invention to form the diffusion barrier sub-layers 350, 360 using more than two materials.

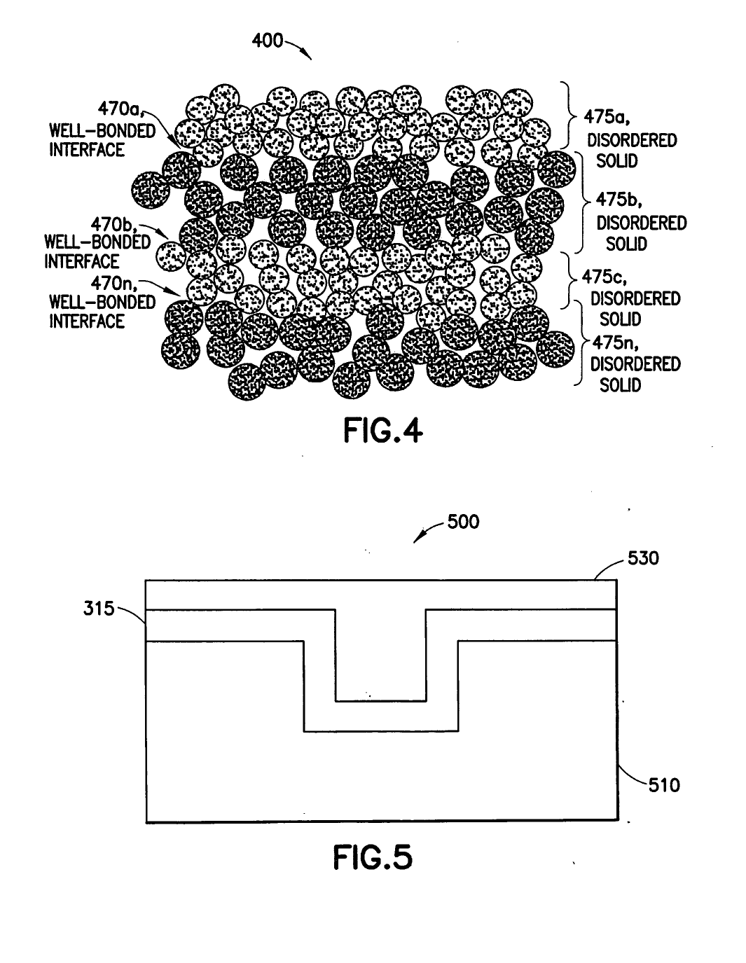

In FIG. 4, an atomic scale magnification of the layers of FIG. 3 is shown. As seen in FIG. 4, the individual layers of FIG. 3 are preferably no more than 2-5 atomic layers thick. Because of the strong binding of the interface 470(a) . . . (n), generally 470, between each of the layers, there is no regular crystal structure in the 2-5 atom thick layer between interfaces 470. This region could be considered to be the ‘bulk’ of each of the layers. The nature of the surface binding energy is such that it dominates the normal tendency for the bulk atoms to form a conventional crystal lattice, in effect, inhibiting the formation of a lattice. Without a regular crystalline lattice, there are no breaks in the lattice that would constitute a grain boundary. Because there are no grain boundaries, the physical effect of work hardening is inhibited, resulting in a diffusion barrier with improved structural flexibility. Therefore, the material of FIG. 4 is a substantially amorphous, multilayer solid material and is highly resistant to the diffusion of a chemical species through the material.

One aspect to forming this class of materials is to choose the correct components for the individual sub-layers. There are at least two major considerations. First, the two materials chosen are preferably immiscible, or have at most only a very minor level (<1%) of solubility. Materials which fit this criterion can be identified by their binary phase diagram, which should show no stable, solid states for compounds with more than a 1% alloy composition. If there is any significant solubility of the two materials chosen, then upon heating they will form a composite alloy and lose the desired multilayer structure.

Second, the two materials selected preferably exhibit good mutual adhesion. This adhesion is necessary to both hold the stack of materials 475(a) . . . (n), generally 475, together as well as to provide the strongly bonded interface 470 which can dominate the bulk material of the film to inhibit crystal lattice formation.

FIG. 5 illustrates a portion of an integrated circuit 500 that includes the diffusion barrier 315, a via 530 and a substrate material 510. The substrate material 510 is preferably comprised of silicon (Si), but it also may be comprised of germanium (Ge), a group III-V material such as gallium arsenide (GaAs), or gallium indium arsenide phosphide (GaInAsP), or a group II-VI material such as mercury cadmium telluride (HgCdTe), or some other suitable substrate material. The diffusion barrier 315 is constructed in accordance with the teachings of this invention so as to contain a plurality of thin layers of alternating materials.

There are a number of examples of materials that can be used to make multilayer atomic laminates that will result in alternating layers of material that do not form lattices, and hence do not form grain boundaries. The choice of the materials used is based on (1) the chemical and metallurgical nature of each layer with the other layers, and (2) the potential for a chemical interaction to occur between the layers chosen and the layers above and below the diffusion barrier film. It is preferred that these considerations also include any changes which might occur at elevated temperature.

In terms of selecting two materials to form the atomic laminates, it is important that these two materials form a strong adhesive bond between the layers. The strength of this bond is important such that the interface between the two materials can effectively dominate the few atomic layers between the bond, inhibiting lattice formation. In addition, it is important that the materials chosen for these alternating layers be stable with increasing temperature and that the two materials have very low solubility with each other at elevated temperature. An example of two materials which fit these criteria are copper (Cu) and tantalum (Ta). The adhesive bond is strong in this case, and there is essentially no mutual solubility of Cu in Ta or Ta in Cu as there are no intermediate compounds in the Cu—Ta binary system. An alternative embodiment may use Ta and TaN, or W and TaN, as these materials also fulfill the criteria of good adhesion and low solubility. However, there are other potential pairs of materials that fit these criteria and that can be used in further embodiments of the invention. For example, the combination of titanium (Ti) and most rare-earth materials such as gadolinium (Gd) would be appropriate, as are materials sets such as, but not limited to, scandium (Sc)-tungsten (W), chromium (Cr)-yttrium (Y), and copper (Cu)-chromium (Cr).

Depending on the application for the diffusion barrier 315, certain materials may be inappropriate because they may either have poor adhesion to the layers above or below the diffusion barrier atomic laminate structure or one of the materials may interact adversely with the adjacent layers. An example of this is the above-mentioned pair of materials Ta and Cu, if used for a diffusion barrier in an interconnect structure composed of Cu circuit elements on a dielectric. While Ta and Cu have good properties from an atomic laminate point-of-view, using Cu in the atomic laminate diffusion barrier may allow Cu interactions with the interlayer dielectric, which the diffusion barrier 315 is intended to prevent. In this case, the Cu in the diffusion barrier laminate may be replaced with scandium (Sc), yttrium (Y), lanthanum (La), tantalum nitride (TaN), or tungsten nitride (WN), or other materials that satisfy the above criteria. It should also be noted that there is no limitation on the use of metals or alloys in the diffusion barrier laminate structure. Depending on the application, layers of nitrides (TaN, TiN, WN, etc) may also be used, either in combination with metal layers or other nitrides. In addition, oxide layers may also be appropriate in some atomic laminate structures, so long as they fit the criteria described above.

It should thus be appreciated that the foregoing examples of materials and thicknesses are not limiting, for example the total thickness of the barrier layer 315 will be a function of the selected constituent elements and/or molecules (e.g. nitride and/or oxides).

However, all such and similar modifications of the teachings of this invention will still fall within the scope of this invention, for example, the invention can be practiced using a variety of materials, and deposition techniques. As is clear from the illustrative examples, alternative embodiments are possible within the scope of the present invention. Further, while the method described herein is provided with a certain degree of specificity, the present invention could be implemented with either greater or lesser specificity, depending on the needs of the user. Other variations of the method within the scope of the present invention will occur to those of ordinary skill in the art. As such, the foregoing description should be considered as merely illustrative of the principles of the present invention, and not in limitation thereof, as this invention is defined by the claims which follow.

1.-43. (canceled)

44. A diffusion barrier comprising a plurality of stacked amorphous sub-layers, each sub-layer having a thickness of about 0.4 to about 4.5 nanometers (nm), wherein the plurality of stacked amorphous sub-layers are arranged collectively to inhibit diffusion of a chemical species through the diffusion barrier, and where the plurality of stacked amorphous sub-layers are three or more stacked amorphous sub-layers, wherein the stacked amorphous sub-layers are of alternating composition, where an amorphous sub-layer of tantalum (Ta) alternates with an amorphous sub-layer of scandium (Sc), wherein the amorphous sub-layers in the diffusion barrier are mutually adhesive.

45. A diffusion barrier as in claim 44, where the plurality of sub-layers in the diffusion barrier are between three and ten in number.

46. A diffusion barrier as in claim 44, wherein the diffusion barrier is a circuit interconnect.

47. A diffusion barrier as in claim 44, wherein each sub-layer has a thickness of about 0.4 to about 1.5 nanometers (nm).

48. A diffusion barrier as in claim 44, wherein the diffusion barrier is electrically conductive.

49. A diffusion barrier comprising a plurality of stacked amorphous sub-layers, each sub-layer having a thickness of about 0.4 to about 4.5 nanometers (nm), wherein the plurality of stacked amorphous sub-layers are arranged collectively to inhibit diffusion of a chemical species through the diffusion barrier, and where the plurality of stacked amorphous sub-layers are three or more stacked amorphous sub-layers, wherein the stacked amorphous sub-layers are of alternating composition, where an amorphous sub-layer of tantalum (Ta) alternates with an amorphous sub-layer of yttrium (Y), wherein the amorphous sub-layers in the diffusion barrier are mutually adhesive.

50. A diffusion barrier as in claim 49, where the plurality of sub-layers in the diffusion barrier are between three and ten in number.

51. A diffusion barrier as in claim 49, wherein the diffusion barrier is a circuit interconnect.

52. A diffusion barrier as in claim 49, wherein each sub-layer has a thickness of about 0.4 to about 1.5 nanometers (nm).

53. A diffusion barrier as in claim 49, wherein the diffusion barrier is electrically conductive.

54. A diffusion barrier comprising a plurality of stacked amorphous sub-layers, each sub-layer having a thickness of about 0.4 to about 4.5 nanometers (nm), wherein the plurality of stacked amorphous sub-layers are arranged collectively to inhibit diffusion of a chemical species through the diffusion barrier, and where the plurality of stacked amorphous sub-layers are three or more stacked amorphous sub-layers, wherein the stacked amorphous sub-layers are of alternating composition, where an amorphous sub-layer of tantalum (Ta) alternates with an amorphous sub-layer of lanthanum (La), wherein the amorphous sub-layers in the diffusion barrier are mutually adhesive.

55. A diffusion barrier as in claim 54, where the plurality of sub-layers in the diffusion barrier are between three and ten in number.

56. A diffusion barrier as in claim 73, wherein the diffusion barrier is a circuit interconnect.

57. A diffusion barrier as in claim 73, wherein each sub-layer has a thickness of about 0.4 to about 1.5 nanometers (nm).

58. A diffusion barrier as in claim 73, wherein the diffusion barrier is electrically conductive.

59. A diffusion barrier comprising a plurality of stacked amorphous sub-layers, each sub-layer having a thickness of about 0.4 to about 4.5 nanometers (nm), wherein the plurality of stacked amorphous sub-layers are arranged collectively to inhibit diffusion of a chemical species through the diffusion barrier, and where the plurality of stacked amorphous sub-layers are three or more stacked amorphous sub-layers, wherein the stacked amorphous sub-layers are of alternating composition, where an amorphous sub-layer of tantalum (Ta) alternates with an amorphous sub-layer of tungsten nitride (WN), wherein the amorphous sub-layers in the diffusion barrier are mutually adhesive.

60. A diffusion barrier as in claim 59, where the plurality of sub-layers in the diffusion barrier are between three and ten in number.

61. A diffusion barrier as in claim 59, wherein the diffusion barrier is a circuit interconnect.

62. A diffusion barrier as in claim 59, wherein each sub-layer has a thickness of about 0.4 to about 1.5 nanometers (nm).

63. A diffusion barrier as in claim 59, wherein the diffusion barrier is electrically conductive.

64. A diffusion barrier comprising a plurality of stacked amorphous sub-layers, each sub-layer having a thickness of about 0.4 to about 4.5 nanometers (nm), wherein the plurality of stacked amorphous sub-layers are arranged collectively to inhibit diffusion of a chemical species through the diffusion barrier, and where the plurality of stacked amorphous sub-layers are three or more stacked amorphous sub-layers, wherein the stacked amorphous sub-layers are of alternating composition, where an amorphous sub-layer of tantalum (Ta) alternates with an amorphous sub-layer of tantalum nitride (TaN), wherein the amorphous sub-layers in the diffusion barrier are mutually adhesive.

65. A diffusion barrier as in claim 64, where the plurality of sub-layers in the diffusion barrier are between three and ten in number.

66. A diffusion barrier as in claim 64, wherein the diffusion barrier is a circuit interconnect.

67. A diffusion barrier as in claim 64, wherein each sub-layer has a thickness of about 0.4 to about 1.5 nanometers (nm).

68. A diffusion barrier as in claim 64, wherein the diffusion barrier is electrically conductive.
